(19) United States
(12) Patent Application Publication
(10) Pub. No.: US 2025/0357239 A1
(43) Pub. Date: Nov. 20, 2025

(54) BROADBAND POWER AMPLIFIER PACKAGE WITH INTEGRATED PROTRUSION HEAT SINK STRUCTURE FOR OPTIMIZED BONDING WIRE LENGTH

(71) Applicant: Korea Electronics Technology Institute, Seongnam-si (KR)

(72) Inventors: Yunsik PARK, Yongin-si (KR); Dongsu KIM, Seongnam-si (KR)

(21) Appl. No.: 19/184,928

(22) Filed: Apr. 21, 2025

(30) Foreign Application Priority Data
May 20, 2024 (KR) 10-2024-0065366

(51) Int. Cl. H01L 23/367; H01L 23/00; H01L 23/13; H01L 23/373; H01L 23/66

(52) U.S. Cl. CPC H01L 23/367; H01L 23/13; H01L 24/48; H01L 23/3735; H01L 23/66; H01L 2223/6655; H01L 2224/48227

(57) ABSTRACT

A power amplifier package is proposed. The power amplifier package may include a heat sink including a protrusion heat sink structure, and a transistor die disposed on a surface of the protrusion heat sink structure. The power amplifier package may also include an insulation board formed on a surface of the heat sink and including an aperture upward exposing the protrusion heat sink structure. The power amplifier package may further include an input and output impedance matching network formed on a surface of the insulation board and electrically connected to the transistor die by a bonding wire.

### CROSS-REFERENCE TO RELATED APPLICATIONS

This application claims the benefit of the Korean Patent Application No. 10-2024-0065366 filed on May 20, 2024, which is hereby incorporated by reference as if fully set forth herein.

### BACKGROUND

### Technical Field

The present disclosure relates to a solid-state power amplifier package, and more particularly, to a power amplifier package which may optimize an internal matching circuit and a heat sink structure in a solid-state power amplifier package with a transistor die embedded therein and may thus implement a broadband characteristic and a high efficiency operation all over an operating frequency band.

### Discussion of Related Technology

Solid-state power amplifiers have a structure where an impedance matching network is integrated into an amplifier, so as to operate in a high frequency band such as a Ku band (a frequency range of about 12 GHz to about 18 GHZ).

### SUMMARY

The present disclosure may apply a heat sink having a good thermal conductive characteristic and a protrusion heat sink structure in a solid-state power amplifier package, and thus, implements broadband impedance matching and a broadband high-efficiency operation characteristic.

For example, the present disclosure may increase a transistor die attachment area to remove a height difference between a matching board and a die and may thus minimize a bonding wire length to implement a low Q-factor matching network, thereby obtaining broadband impedance matching and a broadband frequency characteristic.

Moreover, the present disclosure may apply a heat sink having a good thermal conductive characteristic and a similarity of a coefficient of thermal expansion with a board, and thus, may enable stable heat sink despite a high output power, thereby implementing a high efficiency broadband operation.

Through such object accomplishment, the present disclosure may simultaneously implement a broadband and high efficiency of a solid-state power amplifier which operates in a high frequency band such as a Ku band.

One aspect is a power amplifier package including: a heat sink including a protrusion heat sink structure; a transistor die disposed on a surface of the protrusion heat sink structure; an insulation board formed on a surface of the heat sink and including an aperture upward exposing the protrusion heat sink structure; and an input and output impedance matching network formed on a surface of the insulation board and electrically connected to the transistor die by a bonding wire.

In an embodiment, as a height difference between the transistor die and the input and output impedance matching network is reduced by the protrusion heat sink structure, a length of the bonding wire connecting the transistor die to the input and output impedance matching network may be minimized.

In an embodiment, a thickness of the protrusion heat sink structure may be designed based on a thickness of each of the transistor die and the insulation board.

In an embodiment, the heat sink may include a metal cladding structure.

Another aspect is a power amplifier package including: a heat sink including a lower metal layer, an upper metal layer including a protrusion heat sink structure, and a middle metal layer disposed between the lower metal layer and the upper metal layer; a transistor die disposed on a surface of the protrusion heat sink structure; an insulation board formed on a surface of the upper metal layer and including an aperture upward exposing the protrusion heat sink structure; and an input and output impedance matching network formed on a surface of the insulation board and electrically connected to the transistor die by a bonding wire.

In an embodiment, the lower metal layer and the upper metal layer may include a copper-based material, and the middle metal layer may include a molybdenum-based material.

In an embodiment, as a height difference between the transistor die and the input and output impedance matching network is reduced by the protrusion heat sink structure formed in the upper metal layer, a length of the bonding wire connecting the transistor die to the input and output impedance matching network may be minimized.

According to the present disclosure, a bonding wire length may be minimized by removing a height difference between a matching circuit board and a transistor die, and thus, a broadband impedance matching network of a low Q-factor may be implemented, thereby obtaining a broadband frequency characteristic. Also, the present disclosure may apply a heat sink having a good thermal conductive characteristic and a similarity of a coefficient of thermal expansion with a board, and thus, may enable stable heat sink even in a high output operation, thereby maintaining a high efficiency characteristic all over a broadband.

As a result, the present disclosure may simultaneously implement broadband impedance matching and a high efficiency characteristic in a solid-state power amplifier which operates in a high frequency band such as a Ku band, and thus, may realize a broadband and high efficiency of the solid-state power amplifier.

Particularly, as a bonding wire length is minimized, a broadband characteristic may be considerably enhanced through low Q-factor matching, and thus, a stable broadband operation may be possible under a condition of a high frequency and a high output power.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure.

FIG. 1 is a plan view of a power amplifier package to which a protrusion heat sink structure is applied, according to an embodiment of the present disclosure.

FIG. 2 is a side view of a region A of FIG. 1.

FIG. 3 is a side view of a power amplifier package to which a protrusion heat sink structure of FIG. 2 is not applied.

FIG. 4 is a photograph of a Ku-band power amplifier package actually manufactured by applying a protrusion heat sink structure according to an embodiment of the present disclosure.

FIG. 5 is a result showing a measurement operation performance and a simulation performance of the power amplifier package of FIG. 4.

### DETAILED DESCRIPTION

When designing an internal matching circuit, a Q-factor matching network having a low value is needed for satisfying a high efficiency characteristic and a broadband operation of a power amplifier.

However, under a condition of a high frequency band and a high output power, a Q-factor of a matching network increases due to a parasitic capacitance of a transistor, and due to this, it is difficult to implement a broadband characteristic. Particularly, in a conventional package structure, due to a height difference between a transistor die and a matching circuit board, a wire inductance increases because a long bonding wire is used, and due to this, there is a problem where a Q-factor increases, causing a problem where the conventional package structure has a narrowband characteristic.

Hereinafter, embodiments of the present disclosure will be described in detail with reference to the accompanying drawings. In describing the present disclosure, to facilitate the entire understanding of the present disclosure, like numbers refer to like elements throughout the description of the figures, and a repetitive description on the same element is not provided.

In the following description, the technical terms are used only for explaining a specific embodiment while not limiting the present disclosure. The terms of a singular form may include plural forms unless referred to the contrary. The meaning of ‘comprise’, ‘include’, or ‘have’ specifies a property, a region, a fixed number, a step, a process, an element and/or a component but does not exclude other properties, regions, fixed numbers, steps, processes, elements and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The present disclosure relates to a protrusion heat sink structure to which a solid-state power amplifier package (for example, a solid-state GaN HEMT power amplifier package) and a heat sink material which is good in thermal characteristic. Hereinafter, a detailed embodiment of the present disclosure will be described in detail with reference to the accompanying drawings.

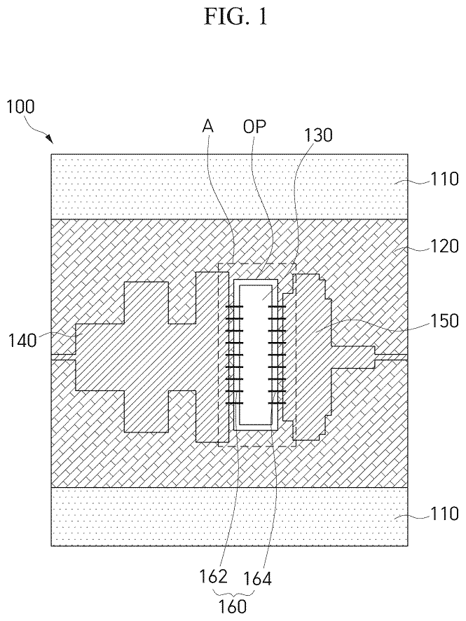

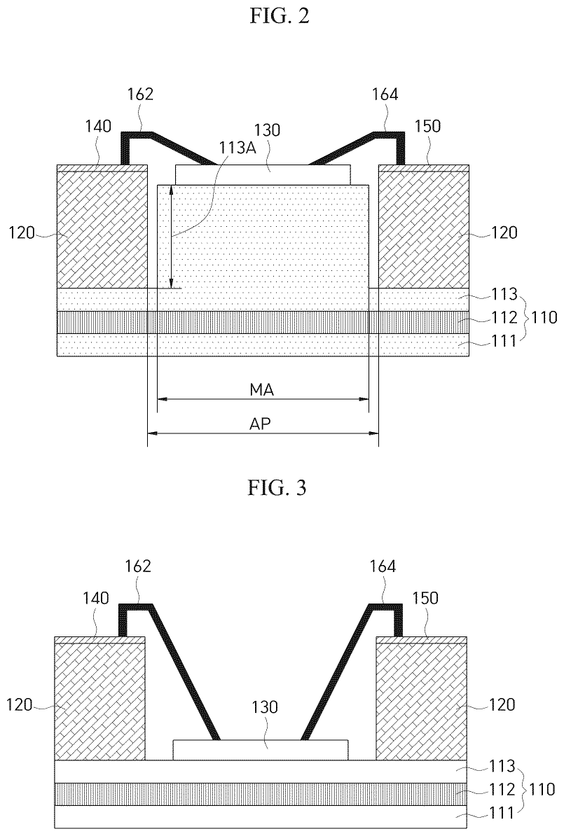

FIG. 1 is a plan view of a power amplifier package to which a protrusion heat sink structure is applied, according to an embodiment of the present disclosure. FIG. 2 is a side view of a region A of FIG. 1.

Referring to FIGS. 1 and 2, a power amplifier package 100 according to an embodiment of the present disclosure may be designed to operate in a Ku frequency band to which a protrusion heat sink structure is applied. To this end, the power amplifier package 100 may include a heat sink 110, an insulation board 120, a transistor die 130, an input impedance matching network 140, and an output impedance matching network 150.

The heat sink 110 may effectively transfer and disperse heat occurring in the power amplifier package 100 (particularly, heat occurring in the transistor die 130). To this end, the heat sink 110 may be configured to include a plurality of layers 111 to 113. The plurality of layers 111 to 113 may include a lower metal layer 111, a middle metal layer 112, and an upper metal layer 113. The lower metal layer 111 may be a layer disposed at a lowermost portion, and for example, may include a copper (Cu)-based material which is good in thermal conductivity. The upper metal layer 113 may be a layer disposed at an uppermost portion, and for example, may include a copper (Cu)-based material, like the lower metal layer 111. The middle metal layer 112 may be a layer disposed between the lower metal layer 111 and the upper metal layer 113, and for example, may include a molybdenum-based material which is good in thermal conductivity. A mounting area MA (hereinafter referred to as a die attachment area) where the transistor die 130 is attached (mounted, disposed, or formed) to a surface of the upper metal layer 113 may be defined. Above all, the die attachment area MA of the upper metal layer 113 may have a structure 113A (hereinafter referred to as a protrusion heat sink structure) which protrudes upward, and the transistor die 130 may be attached to a surface of the protrusion heat sink structure 113A. As described above, the transistor die 130 may be attached to a surface of the protrusion heat sink structure 113A, and thus, lengths of bonding wires 162 and 164 described below may be reduced. A thickness (height) of the protrusion heat sink structure 113A may be appropriately designed based on a thickness (height) of the transistor die 130 and a thickness (height) of an insulation board 120 described below. For example, a thickness of the protrusion heat sink structure 113A may be designed to be a value which is obtained by subtracting the thickness of the transistor die 130 from the thickness of the insulation board 120.

The insulation board 120 may be disposed (formed) on the heat sink 110 or the upper metal layer 113 of the heat sink 110. The insulation board 120 may be aluminum-based (for example, Al₂O₃) or ceramic-based board. The insulation board 120 may include an aperture AP which upward exposes the die attachment area MA. Therefore, the protrusion heat sink structure 113A of the upper metal layer 113 may be disposed in the aperture AP. A shape of the aperture AP may be determined based on a shape of the transistor die 130. For example, as seen above, when a shape of the transistor die 130 is a rectangular shape, a shape of the aperture AP may be a rectangular shape. As seen above, an area of the aperture AP may be designed to be slightly greater than that of the protrusion heat sink structure 113A.

The input impedance matching network 140 and the output impedance matching network 150 may be disposed (formed, patterned, or deposited) on the insulation board 120 with the aperture AP therebetween. That is, the transistor die 130 attached to the surface of the protrusion heat sink structure 113A upward exposed by the aperture AP may be disposed between the input impedance matching network 140 and the output impedance matching network 150. The input impedance matching network 140 may be a circuit pattern which performs input impedance matching, and the output impedance matching network 150 may be a circuit pattern which performs output impedance matching. The input impedance matching network 140 and the output impedance matching network 150 may be electrically connected to the transistor die 130 by the bonding wires 162 and 164. In detail, the input impedance matching network 140 may be electrically connected to an input terminal of the transistor die 130 by an input bonding wire 162, and the output impedance matching network 150 may be electrically connected to an output terminal of the transistor die 130 by an output bonding wire 164.

Furthermore, in an embodiment of the present disclosure, the transistor die 130 may use, for example, a gallium nitride high electron mobility transistor (GaN HEMT) die.

FIG. 3 is a side view of a power amplifier package to which the protrusion heat sink structure of FIG. 2 is not applied.

Referring to FIG. 3, in a power amplifier package to which the protrusion heat sink structure 113A of FIG. 2 is not applied, because a difference between a surface height of the upper metal layer 113 of the heat sink 110 and a surface height of the insulation board 120 occurs, a length of each of the bonding wires 162 and 164 may increase.

However, as illustrated in FIG. 2, in a power amplifier package to which the protrusion heat sink structure 113A of FIG. 2 is applied, the transistor die 130 may be attached to a surface of the protrusion heat sink structure 113A which upward protrudes, and thus, there may be no height difference between a height of the transistor die 130 and a height of the input/output impedance matching network 140/150 formed on a surface of the insulation board 120, thereby minimizing a length of each of the bonding wires 162 and 164.

As a length of a bonding wire is reduced, a parasitic inductance component caused by a wire may decrease, and thus, a Q-factor of an input/output matching network may decrease. A low Q-factor may enable broadband impedance matching, and thus, a broadband operating frequency characteristic of a power amplifier may be obtained.

The following Table 1 may show a result obtained by comparing a bonding wire height with a corresponding bonding wire inductance modeling value in a package before and after a protrusion heat sink structure is applied, and a corresponding value may be an exemplary value in an operating frequency of about 13.2 GHz.

TABLE 1

| | Protrusion heat sink | | Protrusion heat sink | |
|---|---|---|---|---|
| | structure not applied | | structure applied | |
| Bonding wire height | 180 | um | 50 | um |
| Bonding wire inductance | 41 | pH | 33 | pH |

Furthermore, in an embodiment of the present disclosure, a heat sink material may use a material having a value similar to a coefficient of thermal expansion of a board and a good thermal conductive characteristic. In detail, a metal (copper-molybdenum-copper) cladding structure may be applied.

In such a cladding structure, a copper layer may provide a high thermal conductance, and a molybdenum layer may have a low coefficient of thermal expansion. A nickel barrier may be inserted between two layers, and thus, an interface bonding force may increase.

Through such a structure, the present disclosure may simultaneously obtain a good thermal conductive characteristic and a coefficient of thermal expansion similar to a board, and thus, may enable stable heat sink even in a high output operation. When thermal performance is enhanced, a high efficiency characteristic of a power amplifier may be maintained all over a broadband.

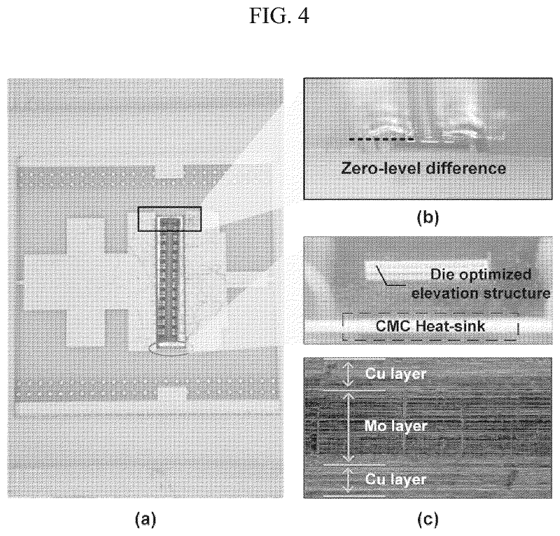

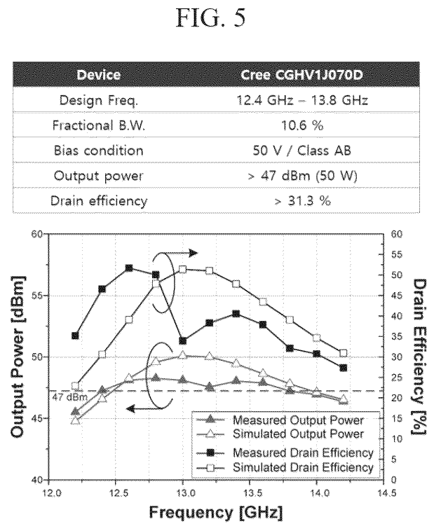

FIG. 4 is a photograph of a Ku-band power amplifier package actually manufactured by applying a protrusion heat sink structure according to an embodiment of the present disclosure, and FIG. 5 is a result showing a measurement operation performance and a simulation performance of the power amplifier package of FIG. 4.

As illustrated in FIGS. 4 and 5, based on a heat sink having a good thermal conductive characteristic and a protrusion heat sink structure according to the present disclosure, broadband impedance matching and a broadband high-efficiency operation may be simultaneously implemented in a solid-state Ku-band power amplifier.

According to the present disclosure, a bonding wire length may be minimized by removing a height difference between a matching circuit board and a transistor die, and thus, a broadband impedance matching network of a low Q-factor may be implemented, thereby obtaining a broadband frequency characteristic. Also, the present disclosure may apply a heat sink having a good thermal conductive characteristic and a similarity of a coefficient of thermal expansion with a board, and thus, may enable stable heat sink even in a high output operation, thereby maintaining a high efficiency characteristic all over a broadband.

As a result, the present disclosure may simultaneously implement broadband impedance matching and a high efficiency characteristic in a solid-state power amplifier which operates in a high frequency band such as a Ku band, and thus, may realize a broadband and high efficiency of the solid-state power amplifier.

Particularly, as a bonding wire length is minimized, a broadband characteristic may be considerably enhanced through low Q-factor matching, and thus, a stable broadband operation may be possible under a condition of a high frequency and a high output power.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A power amplifier package comprising:
a heat sink including a protrusion heat sink structure;
a transistor die disposed on a surface of the protrusion heat sink structure;
an insulation board disposed on a surface of the heat sink and including an aperture upward exposing the protrusion heat sink structure; and
an input and output impedance matching network disposed on a surface of the insulation board and electrically connected to the transistor die by a bonding wire.

2. The power amplifier package of claim 1, wherein, in response to a height difference between the transistor die and the input and output impedance matching network being reduced by the protrusion heat sink structure, a length of the bonding wire connecting the transistor die to the input and output impedance matching network is configured to be minimized.

3. The power amplifier package of claim 1, wherein a thickness of the protrusion heat sink structure is configured to be designed based on a thickness of each of the transistor die and the insulation board.

4. The power amplifier package of claim 1, wherein the heat sink comprises a metal cladding structure.

5. A power amplifier package comprising:
a heat sink including a lower metal layer, an upper metal layer including a protrusion heat sink structure, and a middle metal layer disposed between the lower metal layer and the upper metal layer;
a transistor die disposed on a surface of the protrusion heat sink structure;
an insulation board disposed on a surface of the upper metal layer and including an aperture upward exposing the protrusion heat sink structure; and
an input and output impedance matching network disposed on a surface of the insulation board and electrically connected to the transistor die by a bonding wire.

6. The power amplifier package of claim 5, wherein the lower metal layer and the upper metal layer comprise a copper-based material, and
wherein the middle metal layer comprises a molybdenum-based material.

7. The power amplifier package of claim 5, wherein, in response to a height difference between the transistor die and the input and output impedance matching network being reduced by the protrusion heat sink structure formed in the upper metal layer, a length of the bonding wire connecting the transistor die to the input and output impedance matching network is configured to be minimized.
